(19) United States
(12) Patent Application Publication
(10) Pub. No.: US 2011/0031961 A1
(43) Pub. Date: Feb. 10, 2011

(54) ENDOTRACHEAL TUBE SENSOR

(76) Inventors: Keith V. Durand, Somerville, MA (US); Byron B. Hsu, Danbury, CT (US); Brandon J. Pierquet, Cambridge, MA (US); Warit Wichakool, Cambridge, MA (US); Robert L. Sheridan, Lexington, MA (US); Hongshen Ma, Cambridge, MA (US)

Correspondence Address: NUTTER MCCLENNEN & FISH LLP, SEAPORT WEST, 155 SEAPORT BOULEVARD, BOSTON, MA, 02210-2604, US

(21) Appl. No.: 12/812,116

(22) PCT Filed: Jan. 22, 2009
(86) PCT No.: PCT/US09/31670

§ 371 Date: Oct. 8, 2010

Related U.S. Application Data
(60) Provisional application No. 61/025,993, filed on Feb. 4, 2008.
(60) Provisional application No. 61/113,321, filed on Nov. 11, 2008.

(51) Int. Cl. G01B 7/30; G01R 33/07

(52) U.S. Cl. 324/207.2

(57) ABSTRACT

Various devices and methods for locating an object using magnetic fields are provided. In one embodiment, a device is provided having a housing with an array of sensors that can measure a magnetic field of an object and calculate a three dimensional location of the object based upon the measured magnetic field. A display device for displaying the three dimensional location of the object can also be included. In one exemplary embodiment, an implantable device, such as an endotracheal tube, is provided having the object embedded therein. The array of sensors can be used to measure the magnetic field of the object. The device can then calculate the three dimensional location of the object and the display device can display the calculated location of the object embedded in the implantable device.

### FIELD OF THE INVENTION

The present invention relates to methods and devices for determining the position of an object in a patient's body.

### BACKGROUND OF THE INVENTION

The endotracheal tube (ETT) is a staple of hospital procedures, used to keep the airway of patients open during anesthesia and many surgical procedures. It is inserted to a specific depth in the trachea through either the mouth or nose, or through an incision in the neck. Properly placing this tube requires a high level of skill and training, and tubes misplaced into the esophagus are responsible for numerous cases of mortality and morbidity. If the tube is not inserted far enough, air will no longer be able to enter the patient's lungs. If the tube is inserted too far, air may not reach one of the lungs.

Even a proper insertion can result in later complications, as ETTs can become displaced by sudden movements, or the tubes can gradually migrate over time. There is a need for a reliable method for doctors and nurses to monitor the position of the ETT as patients remain hooked to the breathing machine for hours or days.

Sedating the patient reduces movement due to discomfort, but is not enough. Currently, various tapes and straps are used in an attempt to keep the tube from migrating. While tape can keep the part of the tube external to the patient relatively well-constrained, it is not enough to prevent movement of the ETT internally, and tape can even exacerbate kinking of the tube inside the patient. Because there is no way to prevent tube migration, the medical staff must take active measures to ward off critical situations.

Currently, there are no economical and convenient means of verifying the tube's position in a patient's airway. The usual approach is regular visual inspections of the ETT's position. However, due the high pliability of the tube inside the air passages, a problem may not be externally visible. An X-ray examination can determine the tube's position, but radiography is time consuming, expensive, and exposes the patient to unnecessary radiation. Despite these draw backs, radiography remains the most relied-upon approach for detecting ETT migration.

Other methods have been investigated in the laboratory, but none are fully developed enough for popular use. Examples of these methods include acoustic reflectometry and the measurement of pulmonary compliance.

Accordingly, there remains a need for methods and devices for determining the position of an object in a patient's body, such as an object in an endotracheal tube or other medical device or implant.

### SUMMARY OF THE INVENTION

The present invention generally provides methods and devices for determining the location of an object using magnetic fields. In one embodiment, a device is provided and includes a housing having an array of sensors configured to measure a magnetic field of an object and to calculate a three dimensional location of the object based upon the measured magnetic field. The device can also include a display device for displaying the three dimensional location of the object. The array of sensors can be giant magneto-resistance sensors, Hall-effect sensors, and/or any other appropriate sensors known in the art.

The device can also include an implantable device having the object embedded therein. In one embodiment, the implantable device can be an endotracheal tube. The implantable device can also be a stylet, a suction tube, a catheter, and/or a minimally invasive surgical instrument, and/or any other surgical tool known in the art. The object can also be located within a blocked and magnetically transparent pipe or tube, or the object can be surgical object, such as staples implanted within a human body, that have eddy currents induced therein by a time-varying magnetic field.

In an exemplary embodiment, the display device can be adapted to map the local variations of the magnetic field and to use colors to map a strength of the magnetic field. The housing can also be implemented as a continuous monitoring device that is attached to an exterior of a patient. Alternatively or in addition, the housing can also include a battery, an electronic circuit, a microprocessor, and/or indicator lights that can monitor the position of an endotracheal tube, catheter, or other implantable device.

In an another exemplary embodiment, the device can include a patch configured to be adhered to an exterior of a patient, for example, to an exterior surface of tissue such as the patient's throat, neck, sternum, or chest. The patch can include an array of sensors configured to measure a magnetic field of an object disposed within the patient and to calculate a location of the object based upon the measured magnetic field. The device can also include a display for displaying the calculated location of the object. The patch can include at least one printed circuit board and at least one power source such as a battery. The patch can also be disposable and can have a configuration e.g., a shape or marking, that is adapted to indicate alignment with an anatomical landmark of the patient, for example, the patient's sternal notch. In one embodiment, the display can comprise a plurality of LEDs configured to be aligned along a longitudinal axis of a patient's trachea when the patch is adhered to the patient. The device can also include an implantable device having the object therein or thereon, for example, an endotracheal tube with a magnetic cylindrical collar disposed therearound. The magnetic cylindrical collar can be magnetically polarized in the axial direction to avoid magnetic field inconsistencies caused by axial rotation of the endotracheal tube. In an exemplary embodiment, the patch can be configured to generate at least one of a visible and audible alarm when the implantable device moves out of a desired position, and can be configured to continuously or intermittently monitor a position of the implantable device. In one embodiment, the patch and the implantable device can be sold and/or packaged together to avoid the need to locate the patch prior to implantation.

Methods are also provided for determining the location of an object using magnetic fields. In one embodiment, the method can include positioning an array of sensors in the vicinity of an object to be located, measuring a magnetic field associated with the object, calculating a three-dimensional location of the object based upon the measured magnetic field, and displaying a representation of the three-dimensional location of the object. The array of sensors can include giant magneto-resistance sensors that can measure a magnetic field that is a fraction of the Earth's magnetic field. Alternatively or in addition, the array of sensors can include Hall-effect sensors. The array of sensors can also be used a continuous monitoring device and/or can be attached to an exterior of a patient.

In one exemplary embodiment, the object can be a conductive material having eddy currents produced by a time-varying magnetic field. In another embodiment, the object can be embedded in an endotracheal tube disposed in a patient's esophagus. In still another embodiment, the object can be disposed within a blocked and magnetically transparent pipe or tube.

In displaying the representation of the three-dimensional location of the object, local variations in the magnetic field can be mapped and colors can be used to map the strength of the magnetic field. In one embodiment, the location of the object can be determined using an interpolation or extrapolation algorithm along x and y axes inside and outside of the projection of the sensor array. The measured magnetic field data can be optionally transmitted to a remote device.

### BRIEF DESCRIPTION OF THE DRAWINGS

The invention will be more fully understood from the following detailed description taken in conjunction with the accompanying drawings, in which:

FIG. 1 is a schematic of one exemplary embodiment of a magnetic device;

FIG. 2 is a side view illustration of an endotracheal tube positioned within a patient's trachea;

FIG. 3A is a representation an exemplary operating principle of the device where the magnetic field is imaged using an array of magnetic sensors;

FIG. 3B is a representation of the imaged magnetic fields of FIG. 3A;

FIG. 4A is a schematic of one exemplary embodiment of an AAH-type GMR sensor;

FIG. 4B is a schematic of another exemplary embodiment of an AAH-type GMR sensor;

FIG. 5A is a graphical plot of exemplary GMR sensor output characteristics;

FIG. 5B is another graphical plot of exemplary GMR sensor output characteristics;

FIG. 6 illustrates an exemplary block diagram for a GMR sensor board;

FIG. 7 illustrates an exemplary configuration for observing GMR response to changes in the magnetic field;

FIG. 8 is a graphical plot showing the measured GMR response to changes in the magnetic field;

FIG. 9 is another graphical plot showing the measured GMR response to changes in the magnetic field;

FIG. 10 shows an exemplary embodiment of a display for indicating magnetic field strength in an imagining device;

FIG. 11A is a perspective view of one exemplary embodiment of a housing for an imagining device;

FIG. 11B is an exploded view of the housing of FIG. 10A;

FIG. 12A shows a perspective view of various exemplary embodiments of circuit boards for a device;

FIG. 12B shows a top view of the circuit boards of FIG. 12A;

FIG. 12C shows the circuit boards of FIG. 12A stacked within the housing of FIG. 11A;

FIG. 13A shows a perspective view of one embodiment of a patch adhered to a patient's throat;

FIG. 13B shows a perspective view of the patch of FIG. 13A; and

FIG. 14 shows one embodiment of an endotracheal tube having a magnetic cylindrical collar disposed therearound.

### DETAILED DESCRIPTION OF THE INVENTION

Certain exemplary embodiments will now be described to provide an overall understanding of the principles of the structure, function, manufacture, and use of the devices and methods disclosed herein. One or more examples of these embodiments are illustrated in the accompanying drawings. Those of ordinary skill in the art will understand that the devices and methods specifically described herein and illustrated in the accompanying drawings are non-limiting exemplary embodiments and that the scope of the present invention is defined solely by the claims. The features illustrated or described in connection with one exemplary embodiment may be combined with the features of other embodiments. Such modifications and variations are intended to be included within the scope of the present invention.

The present invention generally provides a device that utilizes an array of sensors to detect and locate a magnetic field of an object disposed within a patient's body. In an exemplary embodiment, the device includes an array of sensors configured to measure a magnetic field of an object and to calculate a three dimensional location of the object based upon the measured magnetic field, and a display device for displaying the three dimensional location of the object. As shown in FIG. 1, the system can also include other components, such as magnetic sensor analog circuitry and a microcontroller. The analog circuitry can amplify the sensor signal to gain a better resolution, and the micro-controller can sample the signal and process the data appropriately for the display or user interface unit. The object can be any magnetic or non-magnetic object, and it can be embedded within a medical implant, tool, or device that is disposed within a patient's body, or it can be an implant, tool, or device.

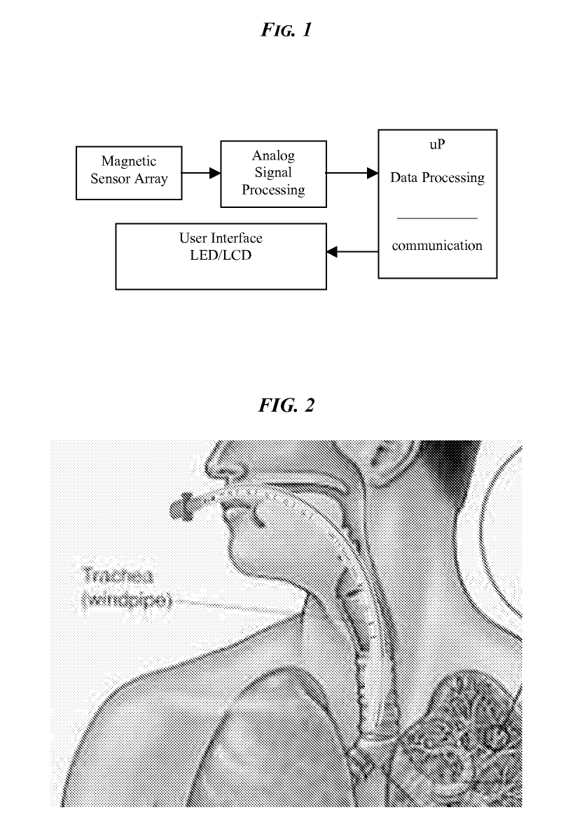

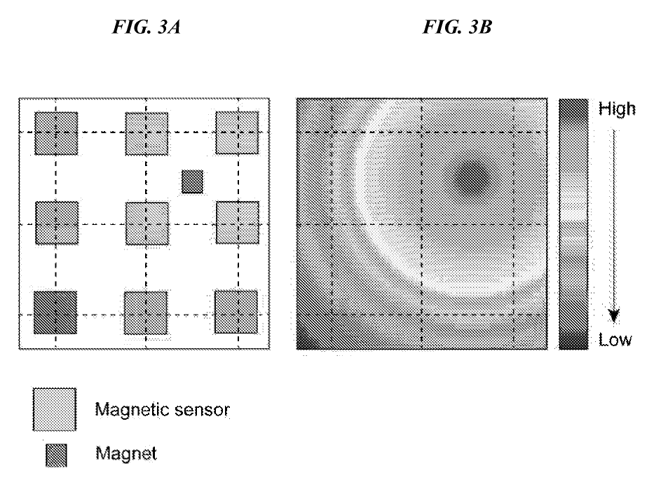

In one exemplary embodiment, the object is embedded in an endotracheal tube, as shown in FIG. 2, to allow a position of the endotracheal tube to be determined when it is inserted within a patient's trachea. As the endotracheal tube is moved along the respiratory system of the patient, the sensor array, e.g., a housing containing the sensor array, can be positioned above the skin surface in the vicinity of the endotracheal tube. As the tube is moved, the display can show the current magnetic field readings from the sensor array and it can indicate the position of a magnet or other object embedded in the endotracheal tube relative to the array of sensors as shown in FIG. 3A. In certain exemplary embodiments and as shown in FIG. 3B, the region where the magnetic field is stronger can be indicated on the display by an indicator, such as a different color (e.g., red), so that the user can intuitively interpret the position of the magnet, and thus the endotracheal tube. In addition, the system can be configured to transmit data wirelessly to a patient monitoring system using any number of methods known in the art. This data can be used as an early warning sign in case the tube migrates and can lower the risk of re-intubation or other complications caused by tube migration.

In another exemplary embodiment, catheters or other objects used in both open and minimally invasive surgical procedures can be tagged with a magnetized object. Magnetic objects can include permanent magnets, temporary magnets, electromagnets, and conductive objects in which eddy currents are induced using a time-varying magnetic field, as well as any other magnetic materials or magnetizable materials known in the art. In the same way as the endotracheal tube described above, a magnetic object can be imbedded in some portion of a device, such as a stylet, suction tube, catheter or other minimally invasive surgical instrument and an array of sensors can be used to measure the field, calculate the three dimension location of the magnetic object, and display the location on a display for a user to read. Further, conductive objects left within the body after surgery, for example, metallic surgical staples, can have eddy currents induced within the objects using a time-varying magnetic field. The array of sensors can be used to sense the magnetic field produced by the eddy currents and then calculate and display the location of the conductive objects within the body. In one embodiment, the array of sensors can be used to locate magnetized objects within locations outside of the human body which are not visible otherwise. For example, the sensors can be used to locate blockages or other magnetic objects within a magnetically transparent pipeline or tube.

The magnetic field of the embedded magnet, magnetic object, and/or conductive object can be measured with many different devices known in the art depending on sample materials, accuracy required, and the nature of measurement. For example, Hall effect sensors can be used, as well as fluxgate sensors, Giant Magnetoresistance (GMR) sensors, Helmholtz coils, and Superconduction Quantum Interface Device (SQUID) sensors. A person skilled in the art will appreciate that any sensors and methods directed toward measuring magnetic fields of any level can be used as needed.

In one exemplary embodiment, a Hall effect sensor can be used to detect and measure the magnetic field of the embedded magnet and/or magnetized object. A Hall effect sensor exploits the fundamental interaction between moving charge and the existing magnetic field to obtain the output voltage measurement. The Hall sensor is most sensitive in the normal direction, which can be useful for detecting the location of a magnet embedded in an ETT. The use of a Hall sensor is advantageous for its low cost and ease of use.

In another exemplary embodiment, a GMR sensor can be used to detect and measure the magnetic field of the embedded magnet. The GMR sensor measures the magnetic field strength (H), which is proportional to the magnetic flux density (B) by the medium permeability constant (μ₀) as B=μ₀H. In some exemplary embodiments, the GMR sensor is more sensitive and has higher bandwidth than the Hall sensor. For example, the AAH002-02 GMR sensor from NVE Corporation has an output sensitivity between 11-18 mV/V-Oe. Exemplary packages of the AAH-type GMR is shown in FIGS. 3A and 3B. For every one Oersted of magnetic field, the sensor outputs about 15 mV per each volt of the supply. One Oersted (Oe) produces a flux of one Gauss (G) in vacuum, which is approximately the same in the air. Optionally, the output can then be amplified with an operational amplifier.

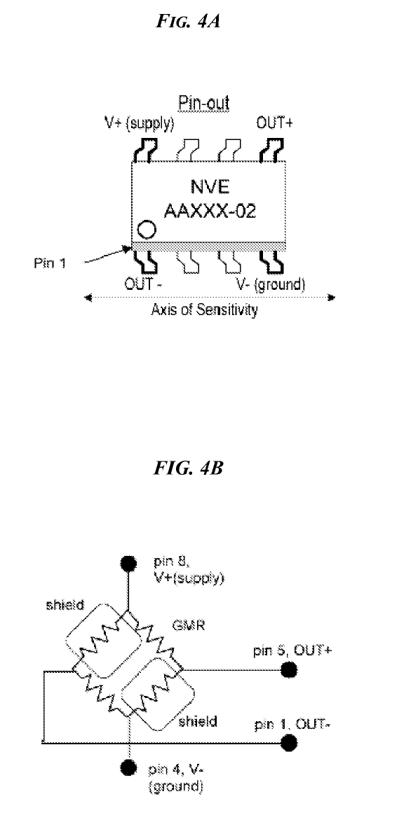

GMR sensor packages are available with different sensitive axes and number of axes can be used to measure the magnetic field of the embedded magnet. For example, some packages offer three dimensional magnetic field measurement, some offer two dimensions, and some offer sensitivity along one direction. In particular, the AAH002-02 sensor is sensitive along the long direction of its SOIC-8 package and has sufficient sensitivity to provide a detectable output in order to estimate the distance from the magnet. One disadvantage of the GMR sensor is hysteresis, which is shown in FIGS. 4A and 4B. The hysteresis causes the response of the GMR to change depending on the state of the GMR at the time of measurement. Accordingly, in an exemplary embodiment, due to the state-dependent characteristic of the GMR sensor, the device can keep a history of the sensor output to accurately determine the magnitude of the applied magnetic field.

The device can also estimate the direction of the magnetic field source as well, which requires multiple sensors. Accordingly, in one exemplary embodiment, an array of GMR sensors is provided as the front-end in order to obtain both the relative magnitude of the magnetic field and the directionality of the source with respect to the current location of the sensor. For example, there can be nine GMR sensors arranged in a 3×3 grid. A 3×3 grid configuration provides the sensitivity needed parallel to the plane that the sensors are mounted in. In addition, the sensitivity of GMR allows for measurement of the normal direction and/or depth information.

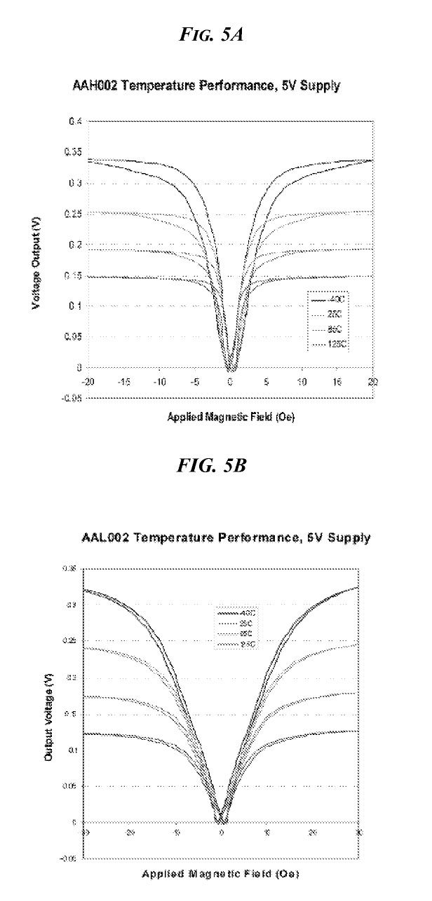

In an exemplary embodiment, one sensor is selected at a time by a multiplexer, for example a ADG726. The sensor output is read as a differential voltage and amplified by a factor of twenty (Gain=20) to increase the signal level precision and dynamic range. An exemplary block diagram for the GMR sensor board is shown in FIG. 5. In one embodiment, INA326 instrumentation differential amplifier can be used with the gain set to twenty (Gain=20). Even though the amplifier has a bandwidth of 1 kHz, the system can measure a constant field with a slow movement. Accordingly, bandwidth is not an issue. A person skilled in the art will appreciate that any appropriate type of instrumentation can be used as needed, as well as an amplifier with any required bandwidth.

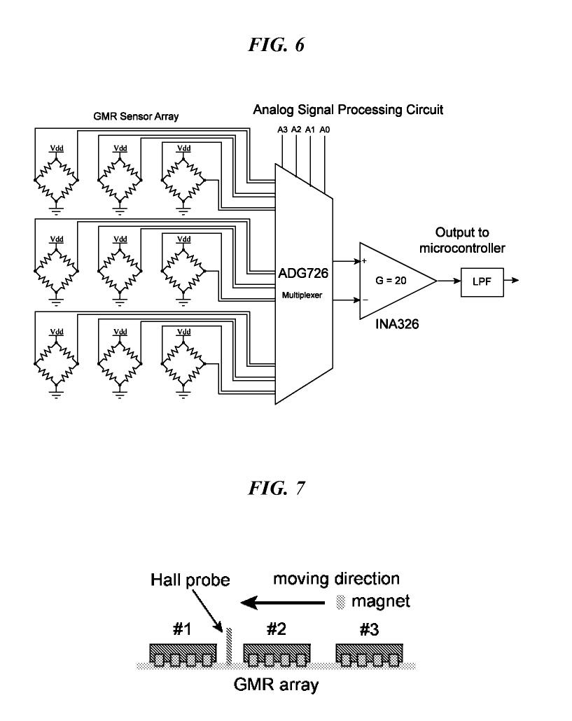

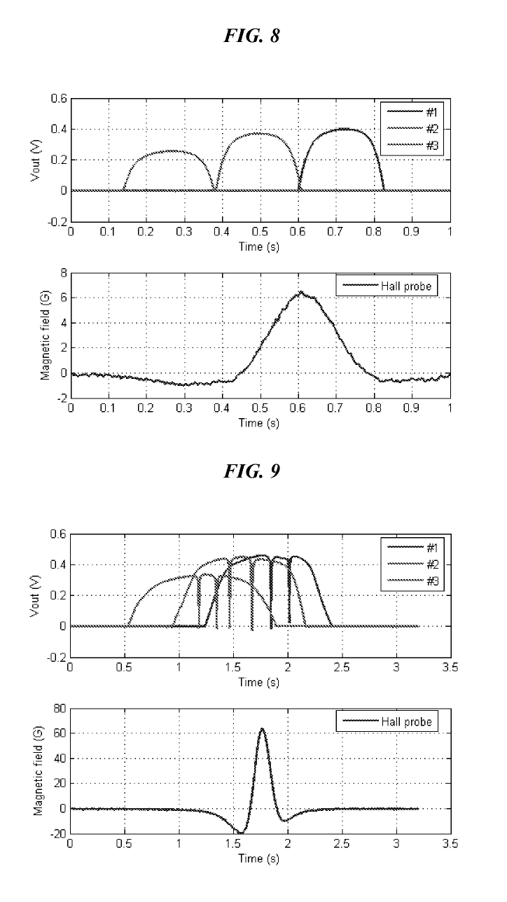

In one example, the initial measurement performed to observe the characteristic of the GMR response to changes in magnetic field was done using a GMR sensor array prototype board, although any mechanism known in the art can be used. In this particular experiment, three GMR sensors were set up along the straight line. A Hall probe was positioned to measure the field along the axis of sensitivity of the GMR package. The experimental setup is shown in FIG. 6. The magnet was moved toward the GMR from one end of the line, in case GMR#3 would sense the field first. The experimental results for two different cases are shown in FIGS. 7 and 8.

In the first experiment, the magnet is lifted up about 15 mm above the sensor plane. The results shown in FIG. 7 show that the sensor output corresponds to the magnetic field strength. The Hall probe confirms that the magnetic field stays within the linear region of the GMR. The maximum field is about 6 G. According to the results, the magnetic field seen at the sensor distance can be as small as 1-2 G. As a reference, the Earth's magnetic field is approximately 0.6 G.

In the second experiment, the sensor is placed about 4 mm away from the magnet. The Hall probe shows that the magnetic field has the sinc pulse shape, as shown in FIG. 8. The field is small but negative when the magnet is far. As the magnet becomes closer, the field becomes more negative. As soon as the magnet passes over the sensor, the field rapidly increases from 20 G to 62.5 G. Finally, the field decay to negative value and return to normal background field level again.

According to the GMR sensor curve shown in FIGS. 4A and 4B and noted above, the particular GMR is a uni-polar device. As a result, the GMR sensor output would corresponds to take the absolute value of the Hall output, scale by a gain factor, and saturate the output to its maximum value. The result shown in FIG. 8 clearly shows that the sensor has crossed the zero crossing twice, where the sharp notches appear. The flat part of the graph corresponds to the saturation level of particular sensor.

The results clearly show that output from the sensor array can provide relative strength of the magnetic field that is correlated to the distance of the magnet measured from the sensor. The sensitivity of GMR is high enough to detect the change in the depth as well. In an exemplary embodiment, the sensor front end can be configured for higher resolution. With the multiple sensors providing a baseline measurement, the permanent magnet can be localized independently of large-scale external magnetic influences, including the earth's magnetic field. In one embodiment, the display can map the local variations of the magnetic field and can use colors to map the strength of the magnetic field.

In another exemplary embodiment, the processing element of the device can digitize the GMR sensor data and compute the X, Y, and Z axis position of the magnet. The processing element can then relay the processed information to the LED driver for display. As an example, an Atmel Atmega 324p can be used for acquisition and processing of the GMR sensor data. The onboard 10-bit Analog to Digital Converter (ADC) of the Atmega324p can be used to sample the sensor data as received from the sensor board. For communications, the FTDI FT232RL USB to RS232 converter chip can be used. The chip allows rapid development of USB devices without detailed knowledge of the USB protocol. The USB port can also used for charging the onboard lithium-polymer battery. In one embodiment, a Maxstream Zigbee module can also be installed on the processing board to facilitate communications wirelessly with a PC, allowing data acquisition for development, and also allowing the possibility of a continuous monitoring system if the device were affixed to the patient.

The device can be powered via a 3.7 V, 860 mAh lithium polymer battery, although a person skilled in the art will appreciate that any appropriate battery known in the art can be used. The battery can be charged whenever the USB port is plugged in to a computer or charger. A MAX1555 can manage the charging of the battery, and a MCP809 combined with a TPS1065D can prevent excessive discharge, which would damage this type of battery. A LDS3985M low dropout regulator can be used to set system bus voltage to 3.3 V.

There are many ways for visualizing the magnetic fields around a patient's neck. For example, a 132×132 pixel color LCD can be installed directly on top of the sensor board. The LCD can be controlled by a microcontroller—the displayed pattern is only limited by display resolution and processor speed. In one embodiment, the display can be divided into nine equal squares. Each square can change color progressively from green to red as the square's associated GMR sensor measures a larger magnetic field. Alternatively, a computer display can be used by using either the USB connection or the Zigbee to transmit serial data to the computer. A Visual Basic program was written that displays colored squares on the computer screen, an example of which can be seen in FIG. 9. A person skilled in the art will appreciate that any display means known in the art can be used, as well as any programming language to program the necessary display. In addition, any software known in the art can be used to produce the same results as needed. Transforming the output of the ADC is essential for obtaining a reasonable response from the display. The gain between the GMR sensor and the ADC is currently set such that the ADC saturates in normal use; this was necessary to obtain adequate spatial resolution with the sensors used.

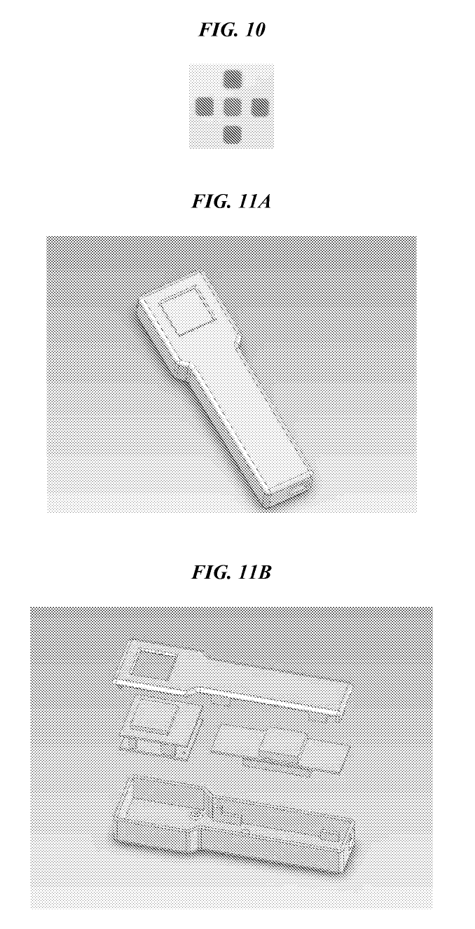

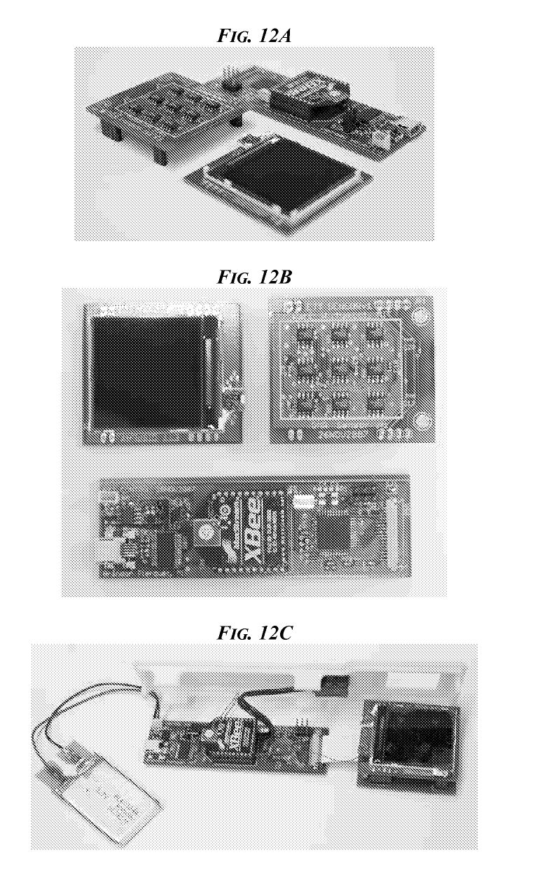

A housing or case to hold the electronic components described above can also be provided. In one exemplary embodiment, tabs are included in both the upper and lower pieces of the housing to locate the internal components. These features can constrain the circuit boards and battery in all directions so that no screws are required to fasten the internal components, although a person skilled in the art will appreciate that any method of constraining the components can be used, including screws, pressed-fit, and/or adhesive. FIG. 10A shows one exemplary model of a housing in the assembled form. FIG. 10B shows the housing in an exploded form. The housing can be fabricated using a Fused Deposition Modeling (FDM) process, for example, or any other fabrication methods known in the art including injection molding.

The housing can be portable and it can have a size and shape to fit comfortably into a user's hand or a pocket. The sensor array can be positioned in the head of the device for ease of use, and the LCD display can be located on the housing directly above the sensor array to intuitively convey the magnet's position. A handle portion of the housing can house the processing circuit as well as the battery and the Zigbee radio. A person skilled in the art will appreciate that the sensor array, display, and handle can be arranged in any configuration as needed and can be formed into any convenient shape and size. For example, the housing or case can be configured to be implemented as a continuous monitoring device and can be configured to be attached to an exterior of a patient. FIGS. 11A and 11B show exemplary embodiments of the circuit boards and the top part of the case. FIG. 11C illustrates how the boards stack and fit into the case.

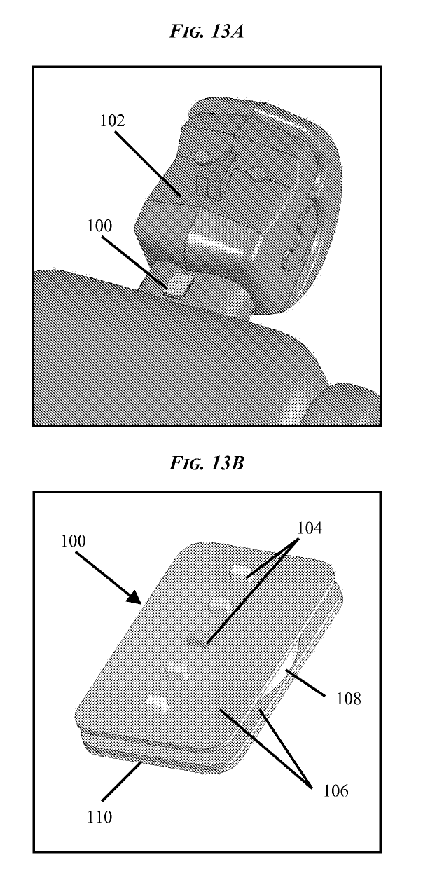

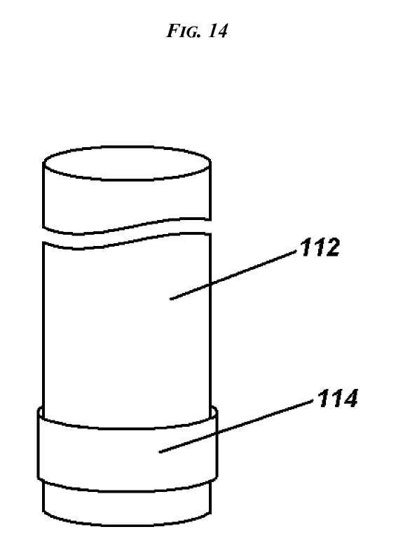

In another exemplary embodiment, as illustrated in FIG. 13A, the device can be a patch 100 that can adhere directly or indirectly to the exterior of a patient 102 in order to monitor the position of an implantable device within the patient. As in the embodiments discussed above, the patch can utilize an array of sensors to detect and locate a magnetic field of an object disposed within the patient's body. In an exemplary embodiment, the patch includes an array of sensors configured to measure a magnetic field of an object disposed in or on an endotracheal tube and to calculate a location of the tube based upon the measured magnetic field. As shown in FIG. 14, the object can be a magnetic cylindrical collar 114 disposed around the endotracheal tube 112. The collar 114 can be magnetically polarized in the axial direction to avoid magnetic field inconsistencies caused by axial rotation of the endotracheal tube 112. One having ordinary skill in the art will appreciate that the object need not be in the form of a magnetic cylindrical collar, but rather can be virtually any type of embedded magnetic tag. As shown in FIG. 13B, the patch 100 can include a plurality of LEDs 104 for displaying the calculated location of the object. In an exemplary embodiment, the LEDs are positioned in a line such that when the patch is adhered to the patient, the line of LEDs runs approximately parallel to the longitudinal axis of the patient's trachea. In one embodiment, the object is positioned at the distal end of the endotracheal tube and the patch is configured to illuminate the LED positioned closest to the object, thereby indicating the approximate position of the distal end of the tube within the patient's throat and/or chest. Such an embodiment is advantageous in that the intuitive LED layout can assist a less trained care-provider in placing the implantable device within the patient. The patch 100 can also include one or more printed circuit boards (PCBs) 106 separated by a power source 108, such as a rechargeable or single-use battery. In one embodiment, the power source 108 is a lithium-ion coil cell capable of powering the patch for up to thirty days.

In an exemplary embodiment, a kit can be provided that includes both an implantable device (e.g., an endotracheal tube) and an inexpensive disposable patch for sensing and/or monitoring the position of the implantable device. The kit elements can be paired such that the electronics and/or sensors of the patch are ideal for detecting and calculating the position of the particular implantable device type or size. For example, where the patient is a child, a relatively small endotracheal tube and relatively small embedded magnetic object can be required. In such cases, the kit can include both the smaller tube and a corresponding patch that includes more sensitive electronics that are capable of accurately detecting the smaller embedded magnetic object. Alternatively, where the patient is an adult with a larger airway that can accommodate a larger tube and embedded object, the kit can include such a tube along with a corresponding patch that can be less sensitive and therefore less expensive. In one embodiment, the kit can include a plurality of patches of varying shapes and sizes to permit the clinician to choose one that more closely corresponds to the size of the patient. Another advantage to packaging and/or selling the patch and the implantable device as a kit is that the need to locate the patch prior to implantation/intubation is avoided.

The patch can be configured to continuously monitor the position of the implantable device or can intermittently monitor its position in order to conserve power. For example, a switch can be provided to permit the clinician to select from a plurality of monitoring frequencies. If the sensor array in the patch detects that the position of the object has changed, or more particularly, has deviated from a desired position, the patch can be configured to generate an audible and/or visible alarm to alert the patient or clinician to the change in position. For example, the patch can be configured to strobe all of the LEDs at once and/or to generate an audible signal using a small piezoelectric speaker.

The patch can be attached to the patient in a number of ways. For example, the patch can include an adhesive film backing 110 to facilitate adherence of the patch to the patient's skin. An adhesive that is non-irritant to human skin is preferred, such as the adhesive commonly used in EKG leads and in consumer bandage products. The patch can alternatively be attached to the patient using tape, bandages, or other materials commonly found in a hospital or patient-care environment. One advantage to embodiments where the sensing device is provided as an adhesive patch is that there is a lower risk of losing the sensing device. Unlike in handheld embodiments, the sensing device of adhesive patch embodiments is affixed to the patient, making it more difficult to misplace.

The patch can be attached to the patient in a variety of locations, e.g., below, near, or on the patient's throat, neck, sternum, chest, etc. One having ordinary skill in the art will appreciate that the particular location and orientation at which the patch is placed on the patient will depend on the location and type of implantable device being monitored. The patch can also be configured, e.g., shaped or marked, to suggest a desired alignment with an anatomical landmark of the patient. For example, the patch can have a contour cut into its edge that is shaped in accordance with a patient's sternal notch. Alternatively or in addition, the patch can include markings printed on its surface that, when aligned with the patient's sternal notch, indicate to a clinician that the patch is placed approximately in line with the patient's trachea. The patch can also be disposable, meaning that it is not re-used for monitoring subsequent patients.

One skilled in the art will appreciate further features and advantages of the invention based on the above-described embodiments. Accordingly, the invention is not to be limited by what has been particularly shown and described, except as indicated by the appended claims. All publications and references cited herein are expressly incorporated herein by reference in their entirety.

What is claimed is:

1. A device, comprising:
a housing having an array of sensors configured to measure a magnetic field of an object and to calculate a three dimensional location of the object based upon the measured magnetic field; and
a display device for displaying the three dimensional location of the object.

2. The device of claim 1, wherein the array of sensors comprise giant magneto-resistance sensors.

3. The device of claim 1, wherein the array of sensors comprise Hall-effect sensors.

4. The device of claim 1, further comprising an implantable device having the object therein.

5. The device of claim 4, wherein the implantable device comprises an endotracheal tube.

6. The device of claim 4, wherein the implantable device is selected from the group consisting of a stylet, a suction tube, a catheter, and a minimally invasive surgical instrument.

7. The device of claim 1, wherein the array of sensors are configured to measure the magnetic field of the object disposed within a blocked and magnetically transparent pipe or tube.

8. The device of claim 1, wherein the display device is configured to map the local variations of the magnetic field.

9. The device of claim 1, wherein the display device is configured to use colors to map a strength of the magnetic field.

10. The device of claim 1, wherein the housing is configured to be implemented as a continuous monitoring device.

11. The device of claim 1, wherein the housing is configured to be attached to an exterior of a patient.

12. The device of claim 1, wherein the housing further comprises a battery, electronic circuit, microprocessor, and indicator lights configured to monitor the position of an endotracheal tube or catheter.

13. The device of claim 1, wherein the implantable device comprises surgical staples having eddy currents induced by a time-varying magnetic field.

14. A method for determining the location of an object using magnetic fields, comprising:
positioning an array of sensors in the vicinity of an object to be located;
measuring a magnetic field associated with the object;
calculating a three-dimensional location of the object based upon the measured magnetic field; and
displaying a representation of the three-dimensional location of the object.

15. The method of claim 14, wherein the array of sensors comprise giant magneto-resistance sensors that can measure a magnetic field within a fraction of the Earth's magnetic field.

16. The method of claim 14, wherein the object is a conductive material having eddy currents produced by a time-varying magnetic field.

17. The method of claim 14, wherein displaying a representation of the three-dimensional location of the object comprises using colors to map the strength of the magnetic field.

18. The method of claim 14, wherein calculating the three-dimensional location of the object comprises using an interpolation or extrapolation algorithm along x and y axes inside and outside of the projection of the sensor array.

19. The method of claim 14, wherein the object is embedded in an endotracheal tube disposed in a patient's esophagus.

20. The method of claim 14, further comprising transmitting the measured magnetic field data to a remote device.

21. The method of claim 14, wherein the array of sensors comprise Hall-effect sensors.

22. The method of claim 14, wherein displaying the representation of the three-dimensional location of the object includes mapping the local variations of the magnetic field.

23. The method of claim 14, wherein displaying the representation of the three-dimensional location of the object includes using colors to map a strength of the magnetic field.

24. The method of claim 14, wherein the array of sensors are used as a continuous monitoring device.

25. The method of claim 14, wherein the array of sensors are attached to an exterior of a patient.

26. A device, comprising:
a patch configured to be adhered to an exterior of a patient, the patch having an array of sensors configured to measure a magnetic field of an object disposed within a patient and to calculate a location of the object based upon the measured magnetic field; and
a display for displaying the calculated location of the object.

27. The device of claim 26, wherein the patch includes at least one printed circuit board and at least one power source.

28. The device of claim 26, wherein the patch is configured to be adhered to an exterior surface of tissue.

29. The device of claim 26, wherein the patch has a configuration that is adapted to indicate alignment with an anatomical landmark of a patient.

30. The device of claim 26, wherein the patch is disposable.

31. The device of claim 26, wherein the display comprises a plurality of LEDs configured to be aligned along a longitudinal axis of a patient's trachea when the patch is adhered to the patient.

32. The device of claim 26, further comprising an implantable device having the object therein.

33. The device of claim 32, wherein the implantable device comprises an endotracheal tube.

34. The device of claim 33, wherein the object is a magnetic cylindrical collar disposed around the endotracheal tube.

35. The device of claim 34, wherein the magnetic cylindrical collar is magnetically polarized in the axial direction.

36. The device of claim 32, wherein the patch is configured to generate at least one of an audible and visible alarm when the implantable device moves out of a desired position.

37. The device of claim 32, wherein the patch is configured to continuously monitor a position of the implantable device.

38. The device of claim 32, wherein the patch is configured to intermittently monitor a position of the implantable device.
